(19) United States
(12) Patent Application Publication
(10) Pub. No.: US 2016/0020427 A1
(43) Pub. Date: Jan. 21, 2016

(54) ORGANIC LIGHT EMITTING DISPLAY APPARATUS AND METHOD OF MANUFACTURING THE SAME

(71) Applicant: Samsung Display Co., Ltd., Yongin-City (KR)

(72) Inventors: Yoonhyeung Cho, Yongin-City (KR); Eungseok Park, Yongin-City (KR); Wonmin Yun, Yongin-City (KR); Byoungduk Lee, Yongin-City (KR); Yunah Chung, Yongin-City (KR); Yongchan Ju, Yongin-City (KR)

(21) Appl. No.: 14/572,544

(22) Filed: Dec. 16, 2014

(30) Foreign Application Priority Data
Jul. 21, 2014 (KR) 10-2014-0092084

(51) Int. Cl. H01L 51/52

(52) U.S. Cl. CPC H01L 51/5256

(57) ABSTRACT

An organic light emitting display apparatus and a method of manufacturing the same. The organic light emitting display apparatus includes a substrate, a display unit disposed on the substrate, a dam unit disposed on the outside of the display unit on the substrate, and an encapsulation layer sealing the display unit, wherein the encapsulation layer includes an organic film covering the display unit and a first inorganic film covering the organic film and the dam unit, and a material of the dam unit is identical with that of the organic film.

### CROSS-REFERENCE TO RELATED APPLICATIONS

Any and all applications for which a foreign or domestic priority claim is identified in the Application Data Sheet as filed with the present application are hereby incorporated by reference under 37 CFR 1.57. This application claims the benefit of Korean Patent Application No. 10-2014-0092084, filed on Jul. 21, 2014, in the Korean Intellectual Property Office, the disclosure of which is incorporated herein in its entirety by reference.

### BACKGROUND

1. Field

The disclosure relates to an organic light emitting display apparatus and a method of manufacturing the same.

2. Description of the Related Technology

Display apparatuses are used to provide users with visual information such as images and text. The display apparatus is being manufactured in various forms to present visual information such as images and text.

Particularly, organic light emitting display apparatuses may be driven at a low voltage with a self-emitting display in which light emitted by exciting an organic material electrically, are easy to make slim, and have a wide viewing angle and a fast response rate, thereby being noted as next-generation displays that may overcome drawbacks indicated as problems of liquid crystal display apparatuses.

Recently, thin film encapsulation (TFE) layers including an organic film and an inorganic film as a unit of sealing an organic light emitting device are being used for slimming and/or flexibilization of the organic light emitting display apparatus.

The TFE layer is a multi-layer thin film structure where the organic film and the inorganic film are alternated. It is advantageous that the number of the films increases in order to prevent moisture, oxygen, and the like from penetrating. However, problems may arise as the production equipment gets enlarged and as a result efficiency of mass production declines as the number of the films increases.

### SUMMARY

One or more embodiments of the present disclosure include an organic light emitting display apparatus where an encapsulation layer is formed with an inkjet printing process, and a method of manufacturing the same.

One or more embodiments of the present disclosure include an organic light emitting display apparatus where an organic film and a dam unit are formed simultaneously, and a method of manufacturing the same.

Additional aspects will be set forth in part in the description which follows and, in part, will be apparent from the description, or may be learned by practice of the presented embodiments.

According to one or more embodiments of the present disclosure, there is provided an organic light emitting display apparatus including a substrate, a display unit disposed on the substrate, a dam unit disposed at an outside of the display unit on the substrate, and an encapsulation layer sealing the display unit. The encapsulation layer includes an organic film covering the display unit and a first inorganic film covering the organic film and the dam unit, and a material of the dam unit is identical with that of the organic film.

A thickness of the organic film may range from about 4 μm to about 40 μm.

The dam unit may be disposed apart from the organic film.

A portion of the first inorganic film may be disposed between the dam unit and the organic film.

The organic film may include at least one selected from silicone, epoxy, and acrylate.

The encapsulation layer may further include a second inorganic film which is disposed between the display unit and the organic film.

The second inorganic film may be disposed between the dam unit and the substrate while covering the display unit.

The dam unit may have a plurality of dams disposed apart from each other and formed side by side.

The first inorganic film may include at least one selected from SiNx, Al₂O₃, SiO₂, and TiO₂.

According to one or more embodiments, there is provided a method of manufacturing an organic light emitting display apparatus including forming a display unit on a substrate, forming an organic film covering the display unit and a dam unit disposed on an outside of the display unit on the substrate with an inkjet printing process, and forming a first inorganic film covering the organic film and the dam unit on the substrate.

A thickness of the organic film may range from about 4 μm to about 40 μm.

A viscosity of the organic film may range from about 10 CPS to about 30 CPS.

A surface tension of the organic film may range from about 20 mN/m to about 50 mN/m.

A material of the organic film and that of the dam unit may be identical.

A portion of the first inorganic film may be disposed between the dam unit and the organic film.

The organic film may include at least one selected from silicone, epoxy, and acrylate.

The first inorganic film may include at least one selected from SiNx, Al₂O₃, SiO₂, and TiO₂.

The method may further include forming a second inorganic film which covers the display unit on the substrate before forming the organic film.

The second inorganic film may be formed between the dam unit and the substrate while covering the display unit.

The dam unit may have a plurality of dams disposed apart from each other and formed side by side.

### BRIEF DESCRIPTION OF THE DRAWINGS

These and/or other aspects will become apparent and more readily understood from the following description of the embodiments, taken in conjunction with the accompanying drawings in which:

FIG. 1 is a cross-sectional view that schematically illustrates an organic light emitting display apparatus according to an embodiment;

FIG. 2 is a cross-sectional view that enlarges and illustrates a display unit of the organic light emitting display apparatus of FIG. 1;

FIG. 3 is a cross-sectional view that schematically illustrates an organic light emitting display apparatus according to another embodiment

FIGS. 4 and 5 are cross-sectional views that schematically illustrate an organic light emitting display apparatus according to another embodiment; and

FIGS. 6 through 8 are reference views that illustrate a method of manufacturing an organic light emitting display apparatus according to an embodiment.

### DETAILED DESCRIPTION

Hereinafter, the present disclosure will be described more fully with reference to the accompanying drawings, in which exemplary embodiments of the invention are shown. This disclosure may, however, be embodied in many different forms and should not be construed as limited to the exemplary embodiments set forth herein. Rather, these embodiments are provided so that this disclosure will be thorough and complete, and will fully convey the scope of the disclosure to one of ordinary skill in the art. Sizes of components in the drawings may be exaggerated for convenience of explanation. In other words, since sizes and thicknesses of components in the drawings are arbitrarily illustrated for convenience of explanation, the following embodiments are not limited thereto.

While such terms as “first” and “second”, may be used to describe various components, such components must not be limited to the above terms. The above terms are used only to distinguish one component from another.

The terms used in the present specification are merely used to describe exemplary embodiments, and are not intended to limit the present disclosure. An expression used in the singular encompasses the expression of the plural, unless it has a clearly different meaning in the context. In the present specification, it is to be understood that the terms such as “including,” “having,” and “comprising” are intended to indicate the existence of the features, numbers, steps, actions, components, parts, or combinations thereof disclosed in the specification, and are not intended to preclude the possibility that one or more other features, numbers, steps, actions, components, parts, or combinations thereof may exist or may be added.

It will be understood that when a component, such as a layer, a film, a region, or a plate, is referred to as being “on” another component, the component can be directly on the other component or intervening components may be present thereon.

As used herein, the term “and/or” includes any and all combinations of one or more of the associated listed items. Expressions such as “at least one of,” when preceding a list of elements, modify the entire list of elements and do not modify the individual elements of the list.

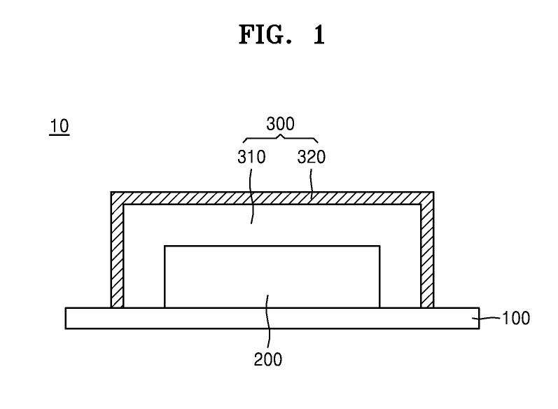

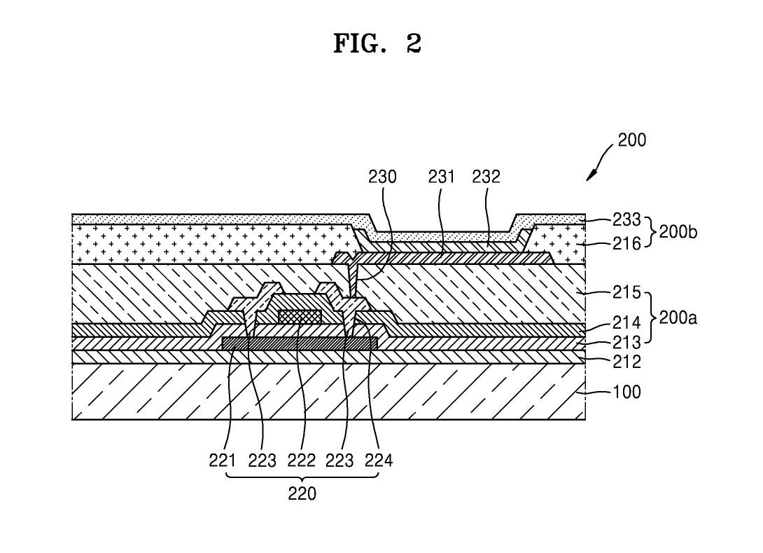

FIG. 1 is a cross-sectional view that schematically illustrates an organic light emitting display apparatus 10 according to an embodiment, and FIG. 2 is a cross-sectional view that enlarges and illustrates a display unit 200 of the organic light emitting display apparatus 10 of FIG. 1.

Referring to FIGS. 1 and 2, an organic light emitting display apparatus 10 according to an embodiment may include a substrate 100, a display unit 200 formed on the substrate 100, and an encapsulation layer 300 sealing the display unit 200.

The substrate 100 may be a flexible substrate and may include plastic with excellent thermal resistance and durability such as polyimide, polyethylene terephthalate (PET), polycarbonate, polyethylene naphthalate, polyacrylate (PAR), and polyetherimide. However, the present disclosure is not limited thereto, and the substrate 100 may include various materials such as metal and glass.

The display unit 200 may have an organic thin film transistor (TFT) layer 200a and a pixel portion 200b. The pixel portion 200b may be an organic light emitting device. Hereinafter, the display unit 200 will be described in detail with reference to FIG. 2.

A buffer layer 212 may be formed on the substrate 100. The buffer layer 212, which prevents penetration of an impure element through the substrate 100 and provides a flat surface to an upper portion of the substrate 100, may be formed with various materials which may perform such a role.

For example, the buffer layer 212 may contain an inorganic material such as silicon oxide, silicon nitride, silicon oxynitride, aluminium oxide, aluminium nitride, titanium oxide, and titanium nitride, or an organic material such as polyimide, polyester, and acrylate and may be formed with a plurality of stacks of the recited materials.

The TFT layer 200a may be formed on the buffer layer 212. While the present embodiment illustrates a top gate type TFT as an example of the TFT layer 200a, a TFT of a different structure may be included.

The TFT layer 200a may include an active layer 221, a gate electrode 222, and a source and a drain electrode 223.

The active layer 221 is formed on the buffer layer 212 by a semiconductor material, and a gate insulating film 213 is formed thereon to cover the buffer layer 212 and the active layer 221. An inorganic semiconductor such as amorphous silicon and polysilicon or an organic semiconductor may be used for the active layer 221, and the active layer 221 has a source region, a drain region, and a channel region between the source region and the drain region. Also, the gate insulating film 213, which is for insulating the active layer 221 and the gate electrode 222, may be formed with an organic material or an inorganic material such as SiNx and SiO₂.

The gate electrode 222 is provided on the gate insulating film 213, and an interlayer insulating film 214 is formed thereon to cover the gate insulating film 213 and the gate electrode 222.

While the gate electrode 222 may contain Au, Ag, Cu, Ni, Pt, Pd, Al, and Mo and may include an alloy such as Al:Nd alloy and Mo:W alloy, the gate electrode 222 is not limited thereto and may be formed with various materials in view of design conditions.

The interlayer insulating film 214, which is disposed between the gate electrode 222 and the source and the drain electrode 223 to insulate the gate electrode 222 and the source and the drain electrode 223, may be formed with an inorganic material such as SiNx and SiO₂.

The source and the drain electrode 223 are formed on the interlayer insulating film 214. Specifically, the interlayer insulating film 214 and the gate insulating film 213 are formed so as to expose the source region and the drain region of the active layer 221, and the source and the drain electrode 223 are formed so as to be in contact with the source region and the drain region of the active layer 221.

Meanwhile, while FIG. 2 illustrates a top gate type TFT sequentially including the active layer 221, the gate electrode 222, and the source and the drain electrode 223, the present invention is not limited thereto, and the gate electrode 222 may be disposed in a lower portion of the active layer 221.

The TFT layer 200a is electrically connected with the pixel portion 200b to drive the pixel portion 200b and is protected with being covered by a planarization film 215.

For the planarization film 215, an inorganic insulating film and/or an organic insulating film may be used. The inorganic insulating film may include SiO₂, SiNx, SiON, Al₂O₃, TiO₂, Ta₂O₅, HfO₂, ZrO₂, BST, and PZT, and the organic insulating film may include a general-purpose polymer (PMMA, PS), a polymer derivative having a phenol-based group, an acrylic-based polymer, an imide-based polymer, an arylether-based polymer, an amide-based polymer, a fluorine-based polymer, a p-xylene based polymer, a vinyl alcohol-based polymer, and blends thereof. Also, the planarization film 215 may be formed with a composite stack of the inorganic insulating film and the organic insulating film.

The pixel portion 200b is formed on the planarization film 215 and may have a pixel electrode 231, an intermediate layer 232, and a counter electrode 233.

The pixel electrode 231 is formed on the planarization film 215 and electrically connected with the source and the drain electrode 223 through a contact hole 230 formed in the planarization film 215.

The pixel electrode 231 may be a reflective electrode and may have a reflective film formed with Ag, Mg, Al, Pt, Pd, Au, Ni, Nd, Ir, Cr, and compounds thereof, and a transparent or translucent electrode layer formed on the reflective film. The transparent or translucent electrode layer may include at least one selected from the group including indium tin oxide (ITO), indium zinc oxide (IZO), zinc oxide (ZnO), indium oxide (In₂O₃), indium gallium oxide (IGO), and aluminum zinc oxide (AZO).

The counter electrode 233 which are disposed to be faced with the pixel electrode 231 may be a transparent or translucent electrode and may be formed with a metal thin film which has a low work function including Li, Ca, LiF/Ca, LiF/Al, Al, Ag, Mg, and compounds thereof. Also, an auxiliary electrode layer or a bus electrode may be further formed on the metal thin film with a material for forming the transparent electrode such as ITO, IZO, ZnO and In₂O₃.

Accordingly, the counter electrode 233 may transmit a light emitted from an organic emission layer included in the intermediate layer 232. That is, the light emitted from the organic emission layer may be reflected by the pixel electrode 231 including a direct or reflective electrode, and thus emitted toward the counter electrode 233.

However, the organic light emitting display apparatus 10 of the present embodiment is not limited to a top-emitting type and may be a bottom-emitting type that the light emitted from the organic emission layer is emitted toward the substrate 100. In this case, the pixel electrode 231 includes the transparent or translucent electrode, and the counter electrode 233 may include the reflective electrode. Also, the organic light emitting display apparatus 10 of the present embodiment may be a dual-emitting type which emits the light toward the top and the bottom in both directions.

Meanwhile, a pixel-defining layer 216 is formed on the pixel electrode 231 as an insulating material. The pixel-defining layer 216 exposes a predetermined region of the pixel electrode 231, and the intermediate layer 232 including the organic emission layer is located on the exposed region.

The organic emission layer may be of a low molecular weight organic material or a polymer organic material, and the intermediate layer 232 may further include a functional layer selectively such as a hole transport layer (HTL), a hole injection layer (HIL), an electron transport layer (ETL), and an electron injection layer (EIL) besides the organic emission layer.

The encapsulation layer 300 seals the display unit 200 and thus prevents the display unit 200 from degrading. The encapsulation layer 300 may include an organic film 310 which is disposed on the substrate 100 while covering the display unit 200, and a first inorganic film 320 which is disposed on the substrate 100 covering the organic film 310 (FIG. 1).

The organic film 310 relieves an internal stress of the first inorganic film 320 or fills in a microcrack and a pinhole of the first inorganic film 320, thereby improving the ability of preventing external moisture or oxygen from penetrating. The organic film 310 may be formed with an inkjet printing process described hereinafter. Accordingly, the organic film 310 may be formed with an organic material which has a lower volatilization point compared to a conventional process, for example, a deposition process by evaporation. For example, an organic film 310 according to the present embodiment may include an organic material with a high volatilization point such as silicone, epoxy, and acrylate. Also, because the organic film 310 is formed with the inkjet printing process, a thick organic film 310 may be formed. Thus, the organic film 310 may range from about 4 μm to about 40 μm.

The first inorganic film 320 may be formed with an inorganic material which has excellent damp proofing ability such as SiNx, Al₂O₃, SiO₂, and TiO₂ to prevent the penetration of external moisture or oxygen. Accordingly, the first inorganic film 320 is formed so as to cover the organic film 310.

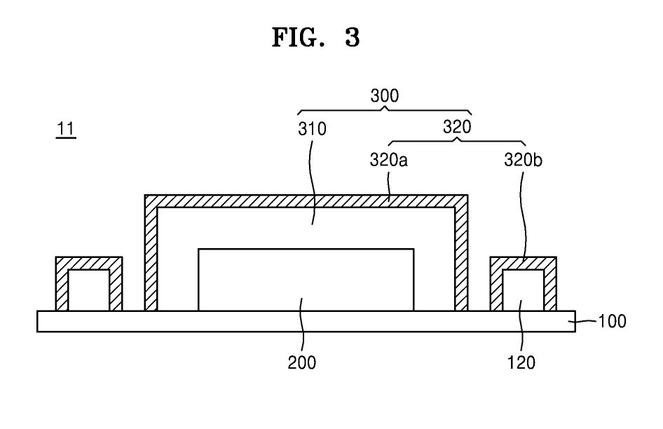

FIG. 3 is a cross-sectional view that schematically illustrates an organic light emitting display apparatus 11 according to another embodiment of the present invention. As illustrated in FIG. 3, the organic light emitting display apparatus 11 may further include a dam unit 120 disposed on a substrate 100 and apart from a display unit 200. The dam unit 120 may be disposed on an outside of the display unit 200 and may be disposed to surround the display unit 200. As the dam unit 120 is present on the outside of the display unit 200, the penetration pathway of moisture or oxygen from an external portion of the organic light emitting display apparatus 11 to the display unit 200 is lengthened, and therefore the permeable resistance of the organic light emitting display apparatus 11 may be further improved.

The dam unit 120 may be formed simultaneously when an organic film 310 is formed and may be formed with the same material as the organic film 310. For example, the dam unit 120 may be formed with an organic material such as silicone, epoxy, and acrylate. The dam unit 120 may prevent the organic film 310 from being exposed to an outside like a conventional edge tail, thereby improving the permeable resistance of a side of the organic light emitting display apparatus 11.

A first inorganic film 320 may be formed on the substrate 100 while covering the organic film 310 and the dam unit 120. A portion of the first inorganic film 320 may be disposed between the organic film 310 and the dam unit 120. The first inorganic film 320 may be divided into a first region 320a covering the organic film 310 and a second region 320b covering the dam unit 120. The first region 320a and the second region 320b may be connected or separate. In FIG. 3, the first region 320a covering the organic film 310 and the second region 320b are shown to be separate. Although the first inorganic film 320 is separate, the permeable resistance of the side of the organic light emitting display apparatus 11 may be improved by the dam unit 120.

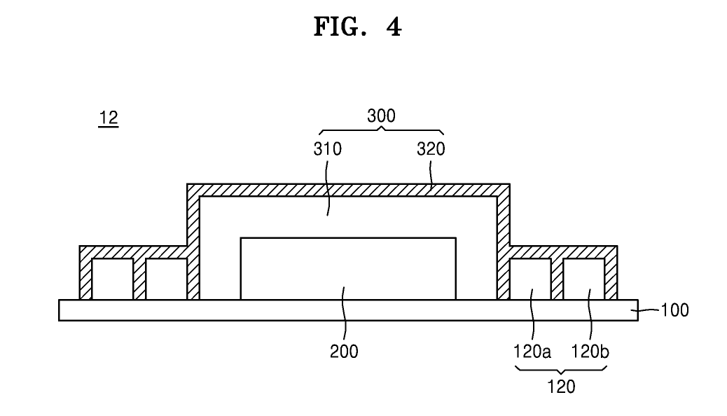

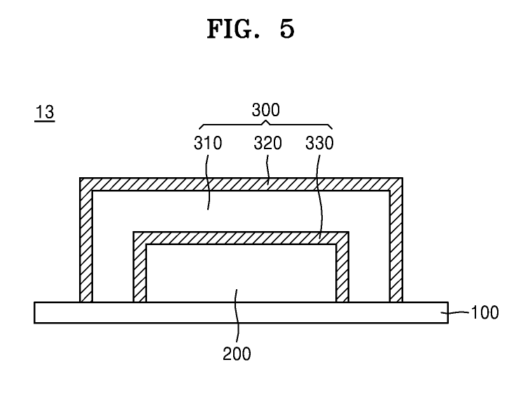

FIGS. 4 and 5 are cross-sectional views that schematically illustrate organic light emitting display apparatuses according to another embodiment of the present invention. As illustrated in FIG. 4, a dam unit 120 may have a plurality of dams 120a and 120b disposed apart from each other to be formed side by side. Because the plurality of dams 120a and 120b surround a display unit 200, a penetration pathway of moisture or oxygen may be further lengthened. Also, a first inorganic film 320 is disposed on a substrate 100 so as to cover an organic film 310 and the dam unit 120.

Otherwise, as illustrated in FIG. 5, an encapsulation layer 300 of the organic light emitting display apparatus 13 may further include a second inorganic film 330 between a display unit 200 and an organic film 310. The second inorganic film 330 may be formed with the same inorganic material as a first inorganic film 320 or a different inorganic material from the first inorganic film 320.

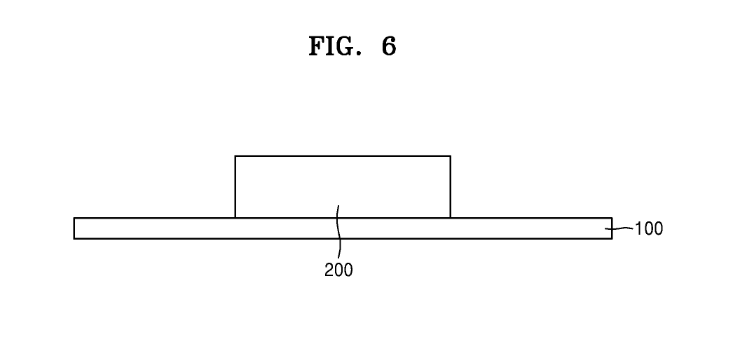

FIGS. 6 through 8 are reference views that illustrate a method of manufacturing an organic light emitting display apparatus according to an embodiment of the present invention. According to the present embodiment, an organic film 310 may be formed with an inkjet printing process. While the method of manufacturing the organic light emitting display apparatus illustrated in FIG. 3 is explained for convenience of explanation, the present embodiment is not limited thereto. The organic light emitting display apparatuses of FIGS. 1, 4, and 5 may also be manufactured with the same method.

First, referring to FIG. 6, a display unit 200 may be formed on a substrate 100.

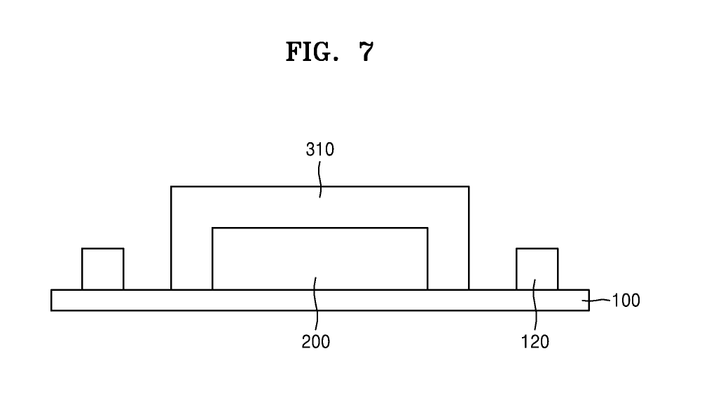

Also, as illustrated in FIG. 7, an organic film 310 covering the display unit 200 and a dam unit 120 disposed apart from the organic film 310 may be formed on the substrate 100. The organic film 310 may be formed so as to cover the display unit 200, and the dam unit 120 may be formed so as to surround the display unit 200. The organic film 310 and the dam unit 120 may be formed with the same organic material. For example, the material forming the organic film 310 and the dam unit 120 may include at least one selected from silicone, epoxy, and acrylate. As the silicone, epoxy, and acrylate have a high volatilization point, it is difficult to perform a deposition process by evaporation. However, in the method of manufacturing the organic light emitting display apparatus according to the present embodiment, the inkjet printing process may be used to form the organic film 310 and the dam unit 120. The inkjet printing process is to jet ink of a silicone, epoxy, or acrylate material on a predetermined position to form the organic film 310 and the dam unit 120. In order to facilitate the inkjet printing process, a viscosity of the ink, that is, the organic film 310 and the dam unit 120 may be low. For example, the viscosity of the organic film 310 and the dam unit 120 may range from about 10 CPS to about 30 CPS. Also, a surface tension of the organic film 310 and the dam unit 120 may range from about 20 mN/m to about 50 mN/m.

Because the inkjet printing allows the ink to be selectively printed on the predetermined position, the organic film 310 and the dam unit 120 which are disposed apart from each other may be formed simultaneously. Accordingly, a process yield ratio may be simplified. In addition, defects according to the use of a mask may be prevented because a selective printing process is used. Also, if the inkjet printing process is used as described above, damage to the display unit 200 may be further prevented compared to forming the organic film 310 and the dam unit 120 with a process, for example, a screen printing process. The reason is that if the organic film 310 is formed with the screen printing process, the display unit 200 may be damaged because a squeeze lever is used.

Also, if the organic film 310 is formed with the inkjet printing process, it is easy to adjust a thickness of the organic film 310, and thus the organic film 310 may be made thicker. Accordingly, the thickness of the organic film 310 as shown in the present embodiment may range from about 4 μm to about 40 μm. An increase in the thickness of the organic film 310 as described above has an effect of improving a progressive dark spot caused by a foreign material.

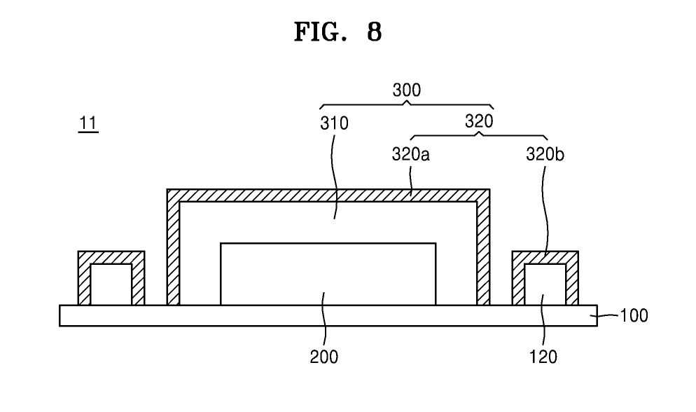

Next, as illustrated in FIG. 8, a first inorganic film 320 may be formed on the substrate 100 so as to cover the organic film 310 and the dam unit 120. The first inorganic film 320 may be formed with sputtering, atomic layer deposition, chemical vapor deposition, and the like. Since the first inorganic film 320 is formed so as to cover the organic film 310, an outside of the organic film 310 is covered with the first inorganic film 320 which has an excellent damp proofing property, and the organic film 310 vulnerable to moisture is not exposed to an outside. Therefore, an encapsulation layer with a very stable permeable resistance may be embodied.

While the above description illustrates that the encapsulation layer 300 includes one organic film 310 and one inorganic film 320, the present invention is not limited thereto, and the organic film 310 and the inorganic film 320 may be formed with being alternately stacked up a plurality of times.

As described above, according to the one or more of the above embodiments of the present disclosure, a thick organic film may be formed because the organic film is formed with an inkjet printing process, and thus a process yield ratio may be reduced.

While one or more embodiments of the present disclosure have been described with reference to the figures, it will be understood by those of ordinary skill in the art that various changes in form and details may be made therein without departing from the spirit and scope of the present invention as defined by the following claims.

What is claimed is:

1. An organic light emitting display apparatus comprising:
a substrate;
a display unit disposed on the substrate;
a dam unit disposed outside of the display unit on the substrate; and
an encapsulation layer sealing the display unit,
wherein the encapsulation layer includes an organic film covering the display unit and a first inorganic film covering the organic film and the dam unit, and a material of the dam unit is identical with that of the organic film.

2. The apparatus of claim 1, wherein a thickness of the organic film ranges from about 4 μm to about 40 μm.

3. The apparatus of claim 1, wherein the dam unit is disposed apart from the organic film.

4. The apparatus of claim 3, wherein a portion of the first inorganic film is disposed between the dam unit and the organic film.

5. The apparatus of claim 1, wherein the organic film comprises at least one selected from silicone, epoxy, and acrylate.

6. The apparatus of claim 1, wherein the encapsulation layer further comprises a second inorganic film which is disposed between the display unit and the organic film.

7. The apparatus of claim 6, wherein the second inorganic film is disposed between the dam unit and the substrate while covering the display unit.

8. The apparatus of claim 1, wherein the dam unit has a plurality of dams disposed apart from each other and formed side by side.

9. The apparatus of claim 1, wherein the first inorganic film comprises at least one selected from SiNx, Al₂O₃, SiO₂, and TiO₂.

10. A method of manufacturing an organic light emitting display apparatus comprising:
forming a display unit on a substrate;
forming an organic film covering the display unit and a dam unit disposed outside of the display unit on the substrate with an inkjet printing process; and
forming a first inorganic film covering the organic film and the dam unit on the substrate.

11. The method of claim 10, wherein a thickness of the organic film ranges from about 4 μm to about 40 μm.

12. The method of claim 10, wherein a viscosity of the organic film ranges from about 10 CPS to about 30 CPS.

13. The method of claim 10, wherein a surface tension of the organic film ranges from about 20 mN/m to about 50 mN/m.

14. The method of claim 10, wherein a material of the organic film and that of the dam unit are identical.

15. The method of claim 10, wherein a portion of the first inorganic film is disposed between the dam unit and the organic film.

16. The method of claim 10, wherein the organic film comprises at least one selected from silicone, epoxy, and acrylate.

17. The method of claim 10, wherein the first inorganic film comprises at least one selected from SiNx, Al₂O₃, SiO₂, and TiO₂.

18. The method of claim 10, further comprising forming a second inorganic film which covers the display unit on the substrate before forming the organic film.

19. The method of claim 18, wherein the second inorganic film is formed between the dam unit and the substrate while covering the display unit.

20. The method of claim 10, wherein the dam unit has a plurality of dams disposed apart from each other and formed side by side.
